(19) United States
(12) Patent Application Publication
(10) Pub. No.: US 2008/0274298 A1
(43) Pub. Date: Nov. 6, 2008

(54) Plant for the Plasma Surface Treatment of an Alveolar Sheet of Plastic Material

(76) Inventors: Francesco Parisi, Torino (IT); Daniel Gallina, Torino (IT)

Correspondence Address: COOK ALEX LTD, SUITE 2850, 200 WEST ADAMS STREET, CHICAGO, IL, 60606, US

(21) Appl. No.: 12/158,169

(22) PCT Filed: Dec. 23, 2005
(86) PCT No.: PCT/IT2005/000760

§ 371 Date: Jun. 19, 2008

(51) Int. Cl. H05H 1/24; C23C 16/513

(52) U.S. Cl. 427/569; 118/723 FE

(57) ABSTRACT

The plant is intended for performing the plasma surface treatment of an alveolar sheet (10) of plastic material having a first and second outer face surface (12, 14) and an inner alveolar surface (16). The plant comprises means able to allow the simultaneous and independent treatment of each of said outer surfaces (12, 14) and inner surface (16) with a respective plasma (96, 98, 100) with which a process fluid is associated, said fluid being deposited on one of said surfaces (12, 14, 16).

The present invention relates to a plant for the plasma surface treatment of an alveolar sheet of plastic material.

One object of the present invention is to provide a plant of the type indicated above, which is operationally simple and reliable and able to ensure a high degree of versatility in terms of performance.

This object is achieved by means of a plant having the features specifically described in claim 1 below. The claims dependent on claim 1 indicate preferential features of the plant according to the invention.

By means of the plant according to the present invention it is possible to perform any combination of treatment of the two outer face surfaces and inner alveolar surface of the sheet. In particular, it is possible to treat all three of these surfaces in a different or similar way or achieve any intermediate condition. Moreover, it is possible to perform the treatment of only one or two of these surfaces and not treat the remaining surface(s).

A further subject of the present invention consists of the use of a plant of the type indicated above for the plasma surface treatment of an alveolar sheet of plastic material.

Further advantages and characteristic features of the present invention will emerge from the detailed description which follows, provided by way of a non-limiting example with reference to the accompanying drawings in which:

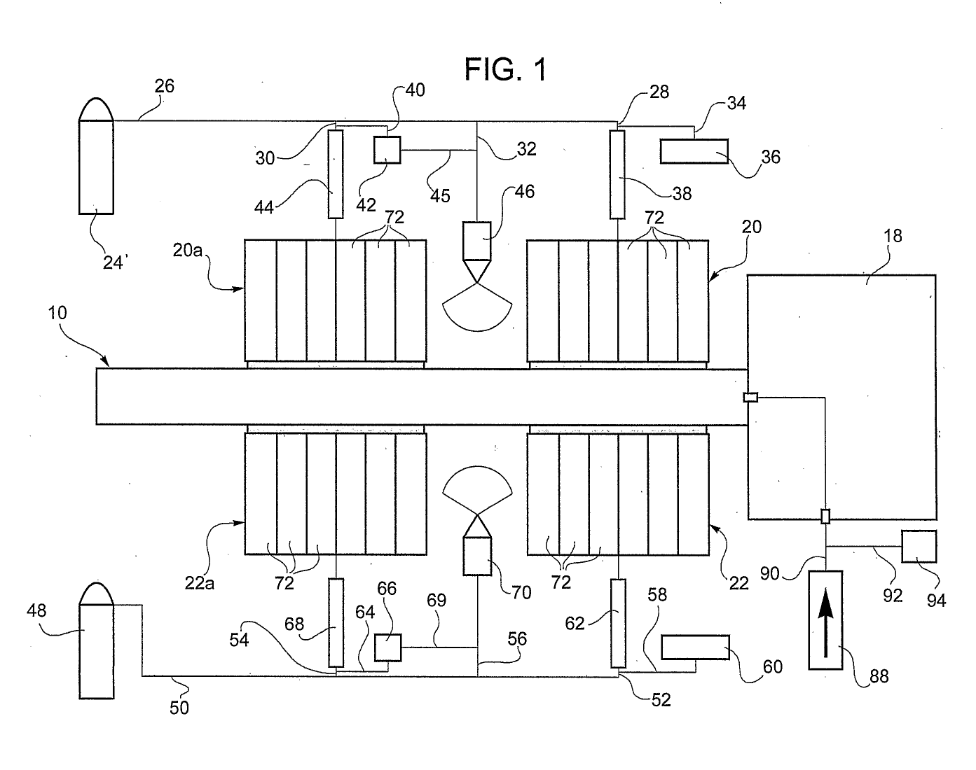

FIG. 1 is a schematic illustration of a plant for the plasma surface treatment of an alveolar sheet of plastic material;

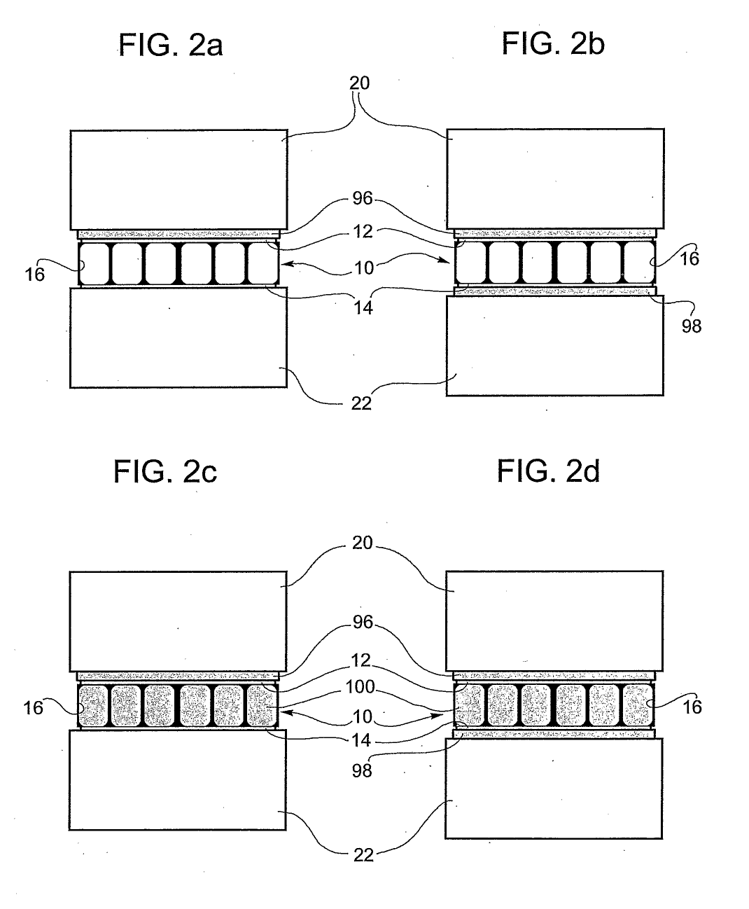

FIGS. 2a to 2d illustrate schematically respective types of surface treatment which can be carried out on the various surfaces of the sheet of plastic material;

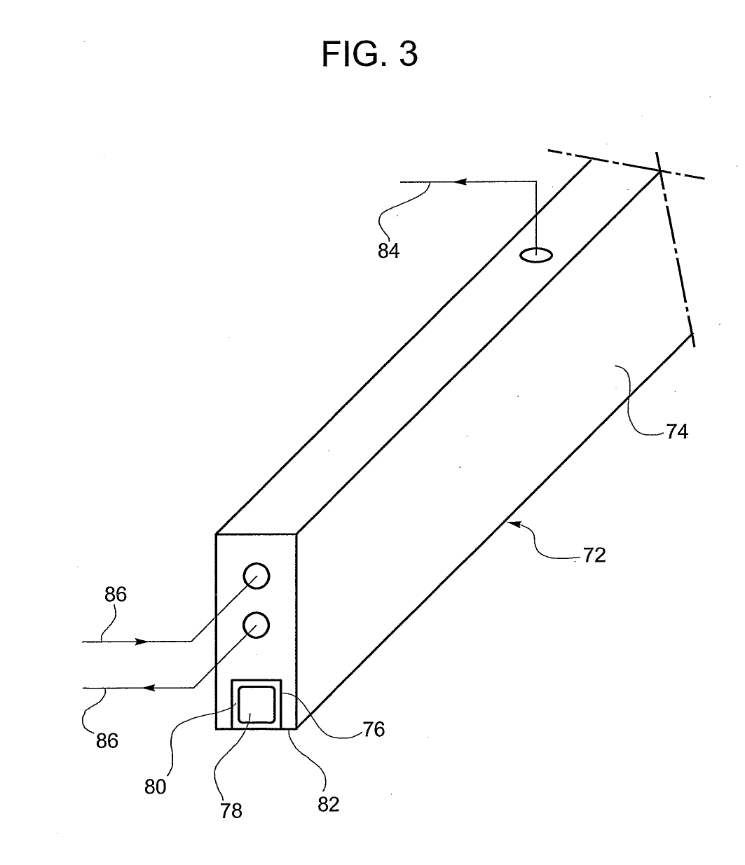

FIG. 3 shows schematically the structure of an element of an electrode of the plant according to FIG. 1;

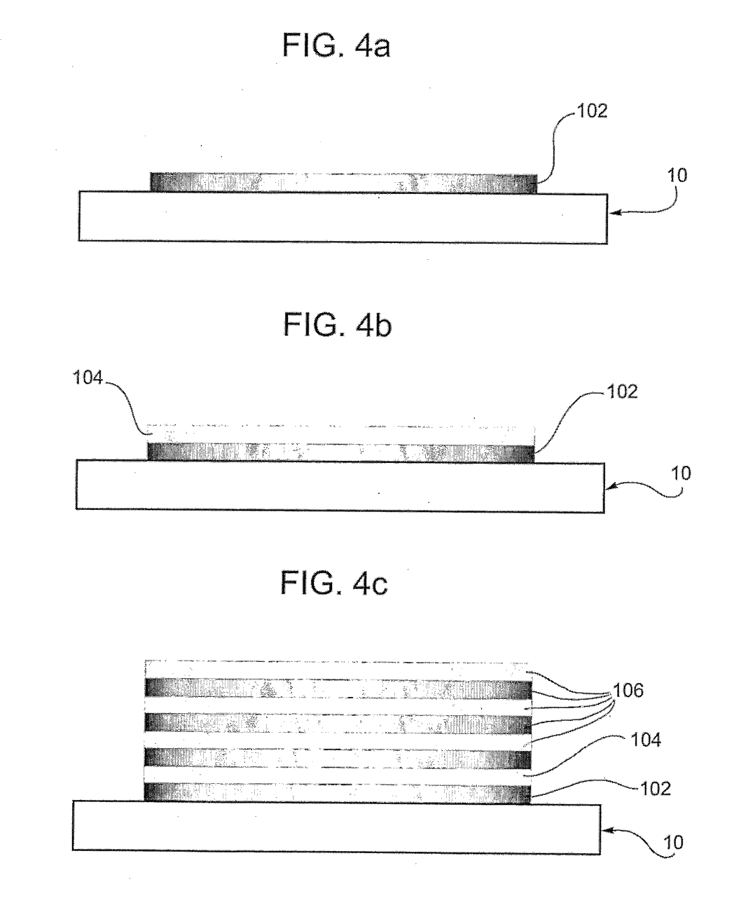

FIGS. 4a to 4c show schematically respective types of surface coating of the sheet of plastic material; and

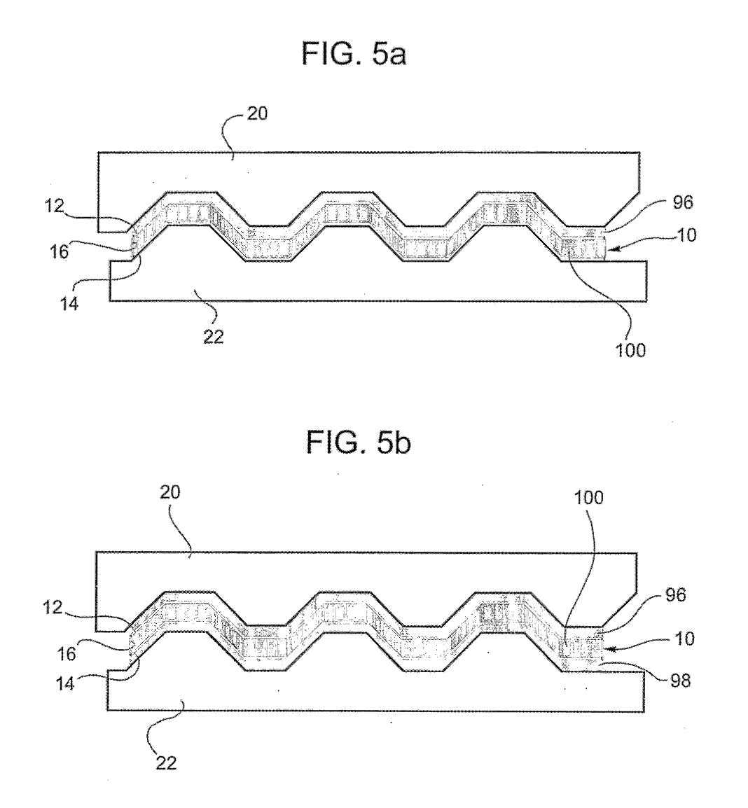

FIGS. 5a to 5b show schematically a variation of embodiment of the plant according to the invention.

FIG. 1 shows schematically a plant for the plasma surface treatment of an alveolar sheet 10 of plastic material having (cf. FIG. 2a) a first outer face surface 12 and a second outer face surface 14 and an inner alveolar surface 16. The sheet 10 may be, for example, a flat sheet of polycarbonate with a thickness of between 10 and 50 mm. FIG. 1 shows, moreover, an extruder 18 which is conventional per se and from which the sheet 10 to undergo plasma treatment is continuously extruded. The plant comprises a first pair of electrodes formed by a first electrode 20 and a second electrode 22 arranged facing each other so as to define an interstice inside which the sheet 10 is displaced and extruded in a direction parallel to that of longitudinal extension of its alveoli. The first and the second electrodes 20, 22 thus face respectively the first and the second outer surface 12, 14 of the sheet 10. The aperture of the interstice may be adjusted by varying the distance at which the first and the second electrodes 20, 22 are arranged.

A second pair of electrodes 20a, 22a having characteristics basically similar to those of the first pair is arranged downstream of the first pair of electrodes 20, 22 (with reference to the displacement of the sheet 10).

The various electrodes are provided with respective means for supplying a carrier gas, able to be converted into plasma, and a process fluid.

The supplying means of the first electrodes 20, 20a include a storage tank 24 for a first carrier gas, from which there extends a delivery line 26 having three branches 28, 30, 32. The branch 28 is joined by a line 34 from a storage tank 36 for a first process fluid. Downstream of this junction the branch 28 has a vaporizer 38 and then leads into the first electrode 20. A line from a storage tank 42 for a first process fluid is joined to the branch 30. Downstream of this junction the branch 30 has a vaporizer 44 and then leads to the first electrode 20a. The branch 32 is joined by a line from the storage tank 42 for a first process fluid. The branch 32 terminates in an atomizer device 46 arranged between the two first electrodes.

The means for supplying the second electrodes 22, 22a include a storage tank 48 for a second carrier gas, from which a delivery line 50 with three branches 52, 54, 56 extends. The branch 52 is joined by a line 58 from a storage tank 60 for a second process fluid. Downstream of this junction the branch 52 has a vaporizer 62 and then leads into the second electrode 22. The branch 54 is joined by a line 64 from a storage tank 66 for a second process fluid. Downstream of this junction the branch 54 has a vaporizer 68 and then leads into the second electrode 22a. The branch 56 is joined by a line 69 from the storage tank 66 for a second process fluid. The branch 56 terminates in an atomizer device 70 arranged between the two second electrodes 22, 22a.

Each first electrode 20, 20a has a modular structure and is formed by a plurality of modular elements 72 arranged in succession. In turn, each element 72 (FIG. 3) comprises a metal body 74 acting as an anode and having, in the portion directed towards the interstice, a cavity 76 which is open outwards and inside which a conductive material acting as a cathode 78 is arranged. A layer of dielectric material 80 lines the walls of the cavity 76 and isolates the anode 74 from the cathode 78, while the surface 82 of the metal body directed towards the sheet 10 is lined with ceramic material, having a high secondary emission coefficient.

The metal body 74 moreover has, formed therein, passages for conveying carrier gas and process fluid, which are directed towards the first face surface 12 of the sheet 10. FIG. 3 shows the inlet opening of the passages which is indicated by the reference number 84.

The metal body 74 is also provided with passages 86 for conveying a diathermic fluid so as to allow the temperature of the element 72 to be controlled in the desired manner.

The second electrodes 22, 22a too have a modular structure and each of them is formed by a plurality of elements substantially similar to those of the first electrodes 20, 20a.

The plant also comprises (FIG. 1) means for supplying into the alveoli of the sheet 10 a third carrier gas, able to be converted into plasma, and a third process fluid. These latter supplying means include a storage tank 88 for the third carrier gas, from which there extends a delivery line 90 joined by a line 92 from a storage tank 94 for the third process fluid. The line 92 then enters into the extruder 18 and emerges opposite the alveoli of the sheet 10 which is being extruded.

During operation of the plant described above, which typically occurs continuously and at atmospheric pressure, the sheet 10 leaving the extruder 18 passes through the interstice defined by the first pair of electrodes 20, 22 at a speed usually of between 1 and 10 m/min and undergoes treatment with the desired process fluids on the various outer face surfaces 12, 14 and inner alveolar surface 16.

By activating only the means supplying the first carrier gas and the first process fluid as well as the passage of electric current between anode 74 and cathode 78 of the elements 72 of the first electrode 20, the formation of plasma 96 is caused between the first electrode 20 and the first outer face surface 12, resulting in the deposition, on the latter, of a layer of the first process fluid (FIG. 2a).

By activating also the means for supplying the second carrier gas and the second process fluid and adjusting the distance of the second electrode 22 from the second outer face surface 14 to a value of between 1 and 5 mm and preferably between 1 and 3 mm, the formation of plasma 98 between the second electrode 22 and the second outer face surface 14 is caused, resulting in the deposition, also onto the latter, of a layer of the second process fluid (FIG. 2b).

Activating instead the means supplying the third carrier gas and the third process fluid causes the formation of plasma 100 inside the alveoli, resulting in the deposition, on their surface 16, of a layer of the third process fluid (FIG. 2c).

Activating simultaneously all the various means supplying the carrier gases and the process fluids causes the deposition, on the various outer face surfaces 12, 14 and inner alveolar surface 16, of the respective process fluids (FIG. 2d).

The various carrier gases used may be identical or different from each other and chosen from among those conventionally used for producing plasma, such as helium for example. The various process fluids used may be identical or different from each other and chosen from among those conventionally used for imparting to the corresponding surface desired properties such as anti-drop, anti-condensation, water-repellent, anti-scratch, anti-UV, IR reflection, conductivity, anti-electrostatic and similar properties. Specific examples of process fluids are tetraethyl orthosilicate, hexamethyl disiloxane, octamethyl cyclotetrasiloxane, di(ethyleneglycol)ethyl ether acrylate, allylic alcohol, allyl amine, acrylic acid, diethylene glycol, glycidyl methacrylate, 3-glycidoxypropyldimethoxysilane, 3-(trimethoxysylil) propyl methacrylate.

The modular structure of the electrodes 20, 22 allows the configuration of the latter to be varied so as to adapt it to the type and to the quantity of process fluid to be applied. Moreover, owing to the presence of the passages 86 for conveying a diathermic fluid inside each element 72, the temperature of the latter may be adjusted independently of each other, so as to allow the formation of the desired temperature profile. The maximum power density which can be withstood by the electrodes 20, 22 is in the region of 100 W/cm².

The sheet 10 provided with a first coating layer 102 (indicated schematically in FIG. 4a with reference to the case where only the first face surface 12 is coated) then passes through the interstice defined by the second pair of electrodes 20a, 22a and undergoes a further treatment in a manner basically similar to that described with reference to the first pair of electrodes 20, 22. FIG. 4b shows (again with reference to the case where only the first face surface 12 is coated) the sheet 10 emerging from the interstice defined by the second pair of electrodes 20a, 22a, with a second coating layer 104 on top of the first layer 102.

In this case, the atomizer device 46 allows delivery, onto the sheet 10, of the first process fluid before plasma treatment which is performed on the already coated sheet 10. By interrupting delivery of the atomizer device 46 it is instead possible to deliver the first process fluid together with the carrier gas into the electrode 20a or it is also possible to adopt a mixed delivery procedure. Using the same first process fluid for supplying the two first electrodes 20, 20a, the two coating layers 102, 104 will have the same chemical nature, albeit with thicknesses which may be different. It is nevertheless possible to use a different first process fluid for plasma treatment carried out in the two first electrodes 20, 20a, thus obtaining coating layers 102, 104 of a different chemical nature.

By arranging further pairs of electrodes (not shown in the figures) downstream of the second pair of electrodes 20a, 22a or by causing the coated sheet 10 to pass again between the interstices defined by the first and second pair of electrodes, it is possible to obtain a multiple-layer coating having a plurality of layers 106 arranged on top of the layers 102 and 104, as shown in FIG. 4c.

FIGS. 5a and 5b show an alternative embodiment of the plant according to the invention in which numbers identical to those used in the preceding figures refer to identical or equivalent parts.

In this case, an undulated sheet 10 of polycarbonate is coated superficially such that the first and second electrode 20, 22 of each pair having facing surfaces with the same undulated profile corresponding to that of the sheet 10. The operating principles of this latter plant are in any case similar to those described above with reference to the plant for coating a flat sheet 10.

FIG. 5a shows, similar to FIG. 2c, the case where the first outer face surface 12 and the inner alveolar surface 16 are coated, while FIG. 5b shows, similar to FIG. 2d, the case where, in addition to these surfaces, the second outer face surface 14 is also coated.

Obviously, without modifying the principle of the invention, the constructional details and the embodiments may be widely varied with respect to that described purely by way of example, without thereby departing from the scope of the invention as defined in the accompanying claims. For example, the plant according to the invention does not have to necessarily be combined with an extruder, but may coat sheets which have been produced in another location and/or some time beforehand.

1. Plant for the plasma surface treatment of an alveolar sheet (10) of plastic material having a first and a second outer face surface (12, 14) and an inner alveolar surface (16), said plant comprising means able to allow the simultaneous and independent treatment of each of said outer surfaces (12, 14) and inner surface (16) with a respective plasma (96, 98, 100) with which a process fluid is associated, said fluid being deposited on one of said surfaces (12, 14, 16).

2. Plant according to claim 1, in which said treatment means comprise at least one first electrode (20) arranged facing the first outer surface (12) of the sheet (10) and provided with means for supplying a first carrier gas, able to be converted into plasma, and a first process fluid.

3. Plant according to claim 2, in which said treatment means comprise a second electrode (22) arranged facing the second outer surface (14) of the sheet (10) opposite the first electrode (20) so as to define an interstice and provided with means for supplying a second carrier gas able to be converted into plasma and a second process fluid.

4. Plant according to claim 2, in which said first electrode (20) has a modular structure and is formed by a plurality of modular elements (72) arranged in succession, each element (72) comprising a metal body (74) acting as an anode and having, in the portion directed towards said interstice, a cavity (76) which is open outwards and inside which conducting material acting as a cathode (78) is arranged, a layer (80) of dielectric material coating the walls of said cavity (76) and isolating the anode (74) from the cathode (78).

5. Plant according to claim 4, in which said metal body (74) is provided with passages (86) for conveying a diathermic fluid, so as to allow the temperature of the element (72) to be controlled.

6. Plant according to claim 4 or 5, in which the surface (82) of the metal body (74) directed towards said sheet (10) is coated with ceramic material having a high secondary emission coefficient.

7. Plant according to any one of the preceding claims, in which said treatment means comprise means for supplying, inside the alveoli of said sheet (10), a third carrier gas able to be converted into plasma and a third process fluid.

8. Plant according to claim 3, in which said first and second electrodes (20, 22) have facing surfaces with the same undulated profile.

9. Plant according to any one of claims 3 to 8, comprising a plurality of pairs of first electrodes (20, 20a) and second electrodes (22, 22a) arranged facing each other, said pairs of electrodes being arranged in succession along the displacement path of the sheet (10) and allowing a series of successive plasma treatments to be carried out on the outer surfaces (12, 14) and inner surface (16) of the sheet (10).

10. Use of a plant according to any one of the preceding claims for the plasma surface treatment, continuously and at atmospheric pressure, of an alveolar sheet (10) of plastic material, in particular polycarbonate, having a first and a second outer face surface (12, 14) and an inner alveolar surface (16).
